(19) United States
(12) Patent Application Publication
(10) Pub. No.: US 2016/0138162 A1
(43) Pub. Date: May 19, 2016

(54) SUBSTRATE PROCESSING APPARATUS

(71) Applicant: Tokyo Electron Limited, Tokyo (JP)

(72) Inventors: Masahide Iwasaki, Miyagi (JP); Yuta Sorita, Miyagi (JP)

(21) Appl. No.: 14/930,953

(22) Filed: Nov. 3, 2015

(30) Foreign Application Priority Data
Nov. 13, 2014 (JP) 2014-230977

(51) Int. Cl. C23C 16/511; C23C 16/455; H01J 37/32; C23C 16/44

(52) U.S. Cl. CPC C23C 16/511; C23C 16/4412; C23C 16/45544; H01J 37/3222; H01J 37/3244

(57) ABSTRACT

A substrate processing apparatus includes: a mounting table configured to place a substrate thereon to be rotatable around an axis; an antenna provided in a first region; and a reaction gas supply section configured to supply a reaction gas to the first region. The reaction gas supply section includes an inside injection port and an outside injection port. The inside injection port is provided at a position closer to the axis than an antenna region when viewed in the axis direction, and configured to inject the reaction gas in a direction getting away from the axis. The outside injection port is provided at a position farther from the axis than the antenna region when viewed in the axis direction, and configured to inject the reaction gas in a direction approaching the axis at a flow rate controlled independently of that of the reaction gas injected from the inside injection port.

### CROSS-REFERENCE TO RELATED APPLICATIONS

This application is based on and claims priority from Japanese Patent Application No. 2014-230977, filed on Nov. 13, 2014, with the Japan Patent Office, the disclosure of which is incorporated herein in its entirety by reference.

### TECHNICAL FIELD

Various aspects and exemplary embodiments of the present disclosure relate to a substrate processing apparatus.

### BACKGROUND

As a kind of a method of forming a film on a substrate, a plasma enhanced atomic layer deposition (PE-ALD) method has been known. In the PE-ALD method, a substrate is exposed to a precursor gas so that the precursor gas containing a constituent element of a thin film is chemically adsorbed on the substrate. Subsequently, the substrate is exposed to a purge gas to remove the precursor gas that is excessively chemically adsorbed on the substrate. Then, the substrate is exposed to the plasma of a reaction gas containing a constituent element of the thin film to form a desired thin film on the substrate. In the PE-ALD method, the above-mentioned processes are repeated so that a film containing the atoms or molecules included in the precursor gas is produced on the substrate.

As one apparatus for implementing the PE-ALD method, a semi-batch type film forming apparatus has been known. In the semi-batch type film forming apparatus, a region for supplying a precursor gas and a region for generating the plasma of a reaction gas are provided as separate regions within a processing chamber, and a substrate sequentially passes through these regions so that a film with a desired thickness is produced on the substrate

Such a film forming apparatus includes a mounting table, a shower head, and a plasma generating unit. The mounting table is configured to support the substrate, and rotates around a rotation shaft. The shower head and the plasma generating unit are disposed to face the mounting table, and are arranged in the circumferential direction. The shower head has substantially a fan shape in plan view, and is configured to supply a precursor gas to a substrate to be processed that passes through the underside of the shower head. The plasma generating unit supplies microwaves to a substantially fan-shaped antenna from a waveguide, and supplies a reaction gas from an area of the antenna to generate the plasma of the reaction gas within the area of the antenna. An exhaust port is provided around the shower head and around the plasma generating unit, and injection ports for supplying a purge gas are provided at the periphery of the shower head. See, e.g., International Publication No. WO 2013/122043.

### SUMMARY

The present disclosure provides substrate processing apparatus including: a mounting table configured to place a substrate to be processed (“substrate”) thereon, and provided to be rotatable around an axis such that the substrate is moved around the axis; an antenna provided in a plasma processing region which is one region among a plurality of regions, through which the substrate sequentially passes while moving in a circumferential direction around the axis due to rotation of the mounting table; and a gas supply section configured to supply a reaction gas to the plasma processing region. The gas supply section includes: an inside injection port provided at a position closer to the axis than the antenna when viewed in a direction of the axis, and configured to inject the reaction gas in a direction getting away from the axis, and an outside injection port provided at a position farther from the axis than the antenna when viewed in the direction of the axis, and configured to inject the reaction gas in a direction approaching the axis at a flow rate which is controlled independently of a flow rate of the reaction gas injected from the inside injection port.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a sectional view illustrating an exemplary substrate processing apparatus.

FIG. 2 is a schematic view illustrating the exemplary substrate processing apparatus when viewed from the upper side.

FIG. 3 is a sectional view illustrating an example of a left portion of the axis X in FIG. 1 in an enlarged scale.

FIG. 4 is a sectional view illustrating an example of a left portion of the axis X in FIG. 1 in an enlarged scale.

FIG. 5 is a view illustrating an example of a bottom surface of a unit U.

FIG. 6 is a sectional view illustrating an example of a right portion of the axis X in FIG. 1 in an enlarged scale.

FIG. 7 is a schematic view illustrating an exemplary substrate processing apparatus of Example 1 when viewed from the upper side.

FIG. 8 is a sectional view illustrating the exemplary substrate processing apparatus in Example 1.

FIG. 9 is a schematic view illustrating an exemplary substrate processing apparatus of Example 2 when viewed from the upper side.

FIG. 10 is a sectional view illustrating the exemplary substrate processing apparatus in Example 2.

FIG. 11 is a schematic view illustrating an exemplary substrate processing apparatus of Example 3 when viewed from the upper side.

FIG. 12 is a sectional view illustrating the exemplary substrate processing apparatus in Example 3.

FIG. 13 is a view illustrating examples of a film thickness distribution on a substrate in Examples 1 to 3, when a flow rate of a reaction gas and an RDC were changed.

FIG. 14 is a view illustrating examples of a film thickness distribution on a substrate in Examples 1 to 3, when a flow rate of a reaction gas and an RDC were changed.

FIG. 15 is a view illustrating examples of a film thickness distribution on a substrate in Examples 1 to 3, when a flow rate of a reaction gas and an RDC were changed.

FIG. 16 is a view illustrating examples of a film thickness distribution on a substrate in Examples 1 to 3, when a flow rate of a reaction gas and an RDC were changed.

FIG. 17 is a view illustrating examples of a film thickness distribution on a substrate in Examples 1 to 3, when a flow rate of a reaction gas and an RDC were changed.

FIG. 18 is a view illustrating examples of a film thickness distribution on a substrate in Examples 1 to 3, when a flow rate of a reaction gas and an RDC were changed.

FIG. 19 is a schematic view illustrating an exemplary substrate processing apparatus of Example 4 when viewed from the upper side.

FIG. 20 is a view illustrating examples of a film thickness distribution on a substrate in Examples 1, 4, and 5 when a flow rate of a reaction gas was changed.

FIG. 21 is a view illustrating a hatched portion of FIG. 20 in an enlarged scale.

FIG. 22 is a view illustrating examples of a film thickness distribution on a substrate in Examples 1, 4, and 5 when a flow rate of a reaction gas was changed.

FIG. 23 is a view illustrating a hatched portion of FIG. 22 in an enlarged scale.

FIG. 24 is a view illustrating examples of a film thickness distribution on a substrate in Examples 1, 4, and 5 when a flow rate of a reaction gas was changed.

FIG. 25 is a view illustrating a hatched portion of FIG. 24 in an enlarged scale.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the semi-batch type film forming apparatus disclosed in the document described above, the film thickness distribution from the rotation center of the mounting table on the substrate in the radial direction of the mounting table has a lower uniformity than the film thickness distribution in the rotation direction of the mounting table. Therefore, in the semi-batch type film forming apparatus, what is requested is to improve the controllability of a film thickness distribution such as, for example, the uniformity of the film thickness from the rotation center of the mounting table on the substrate in the radial direction of the mounting table.

According to an aspect of the present disclosure, a substrate processing apparatus includes a mounting table, an antenna, and a gas supply section. The mounting table is configured to place a substrate to be processed (“substrate”) thereon, and provided to be rotatable around an axis such that the substrate is moved around the axis. The antenna is provided in a plasma processing region which is one region among a plurality of regions, through which the substrate sequentially passes while moving in a circumferential direction around the axis due to rotation of the mounting table. The gas supply section is configured to supply a reaction gas to the plasma processing region. The gas supply section includes an inside injection port and an outside injection port. The inside injection port is provided at a position between the antenna and the axis when viewed in a direction of the axis, and configured to inject the reaction gas in a direction getting away from the axis from a position closer to the axis than the antenna. The outside injection port is provided at a position farther from the axis than the antenna when viewed in the direction of the axis, and configured to inject the reaction gas in a direction approaching the axis from the position farther from the axis than the antenna at a flow rate which is controlled independently of a flow rate of the reaction gas injected from the inside injection port.

In the substrate processing apparatus, the inside injection port and the outside injection port inject the reaction gas toward a region where the antenna is provided when viewed in the direction of the axis.

In the substrate processing apparatus, the inside injection port and the outside injection port inject the reaction gas toward a direction parallel to a surface of the substrate placed on the mounting table.

In the substrate processing apparatus, the gas supply section includes a plurality of inside injection ports and a plurality of outside injection ports.

In the substrate processing apparatus, a plurality of antennas are provided in the plasma processing region, and at least one inside injection port and at least one outside injection port are allocated to each of the antennas, and a flow rate of the reaction gas to be injected for each of the antennas is independently controllable.

The substrate processing apparatus further includes an exhaust region provided along a periphery of the mounting table and configured to perform exhaust from a plurality of exhaust ports. The exhaust section is provided in a region that is different from a region of an angle where the antenna is provided when viewed in a direction of the axis.

In the substrate processing apparatus, the plurality of exhaust regions are provided along the periphery of the mounting table.

In the substrate processing apparatus, exhaust amounts from the respective exhaust regions are equal to each other.

According to an aspect of the substrate processing apparatus of the present disclosure, the controllability of the film thickness distribution on the substrate may be improved in the radial direction of the mounting table from the rotation center of the mounting table.

Hereinafter, an exemplary embodiment of a substrate processing apparatus according to a disclosure will be described in detail based on drawings. Also, the disclosure is not limited by the present exemplary embodiment. Respective exemplary embodiments may be properly combined with each other within a range that does not contradict the processing contents.

### Exemplary Embodiment

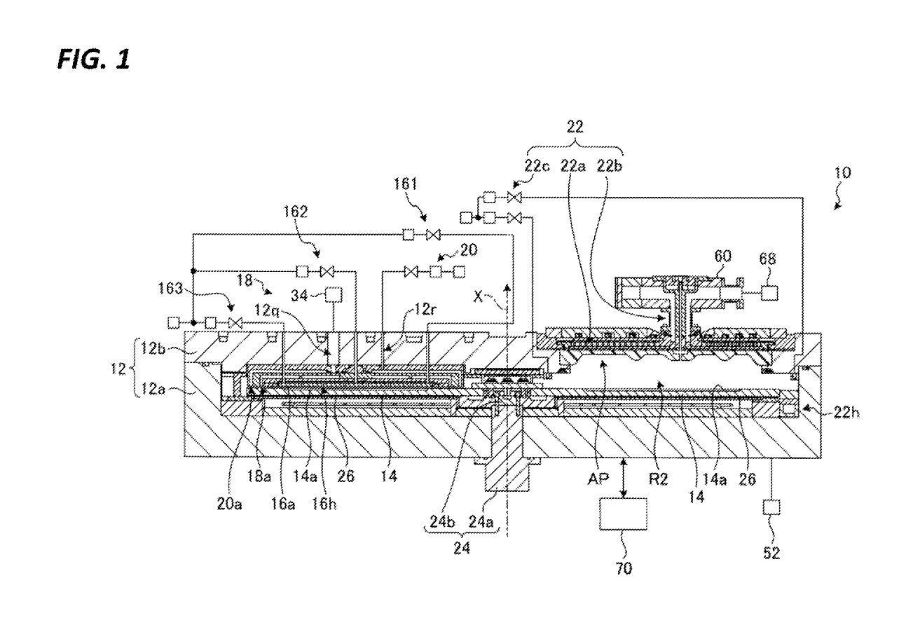

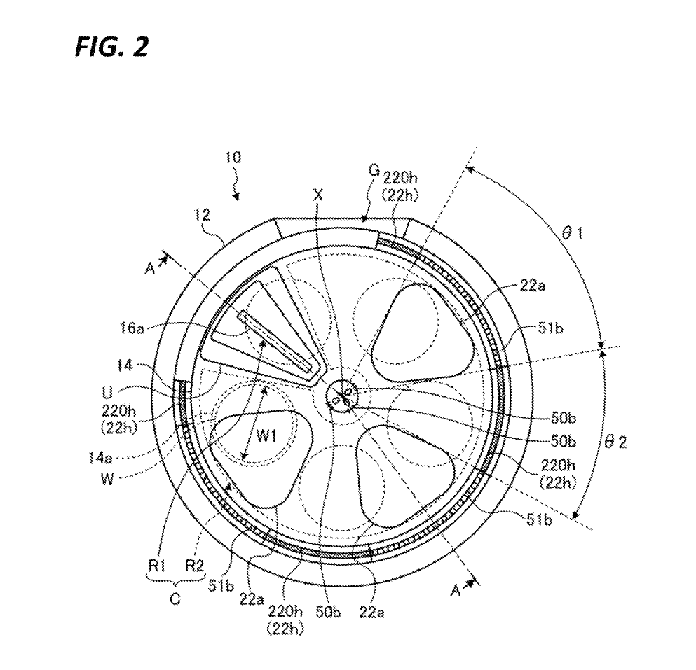

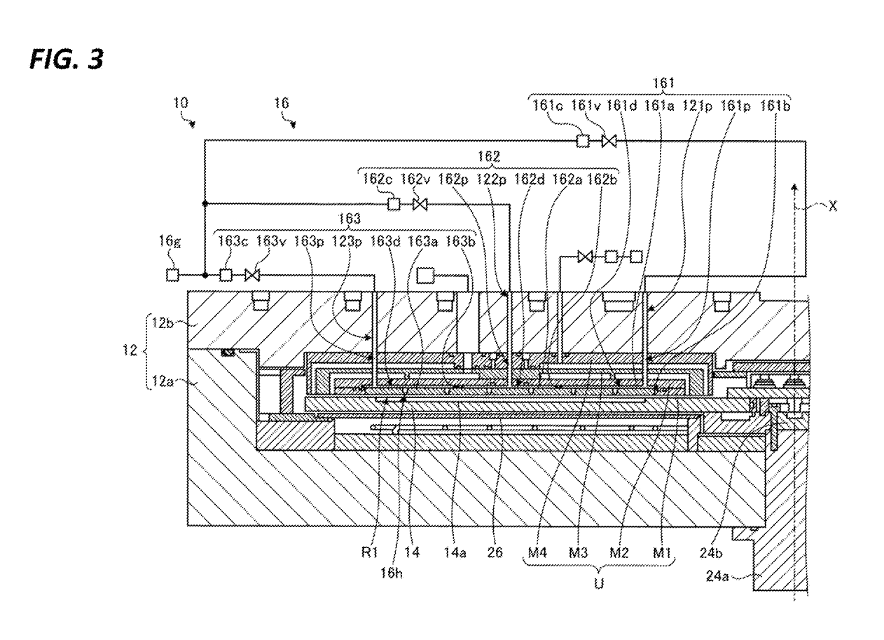

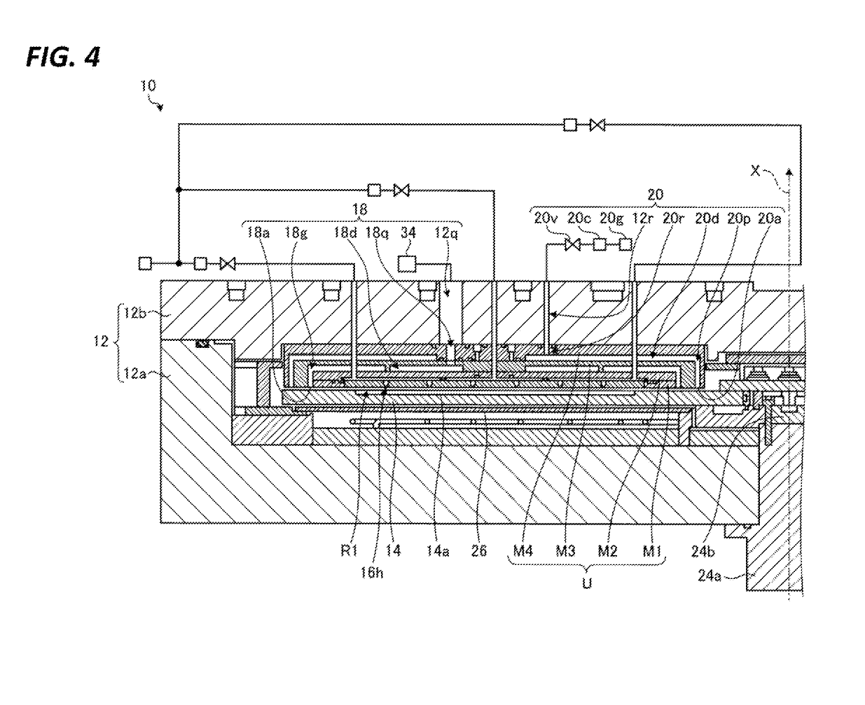

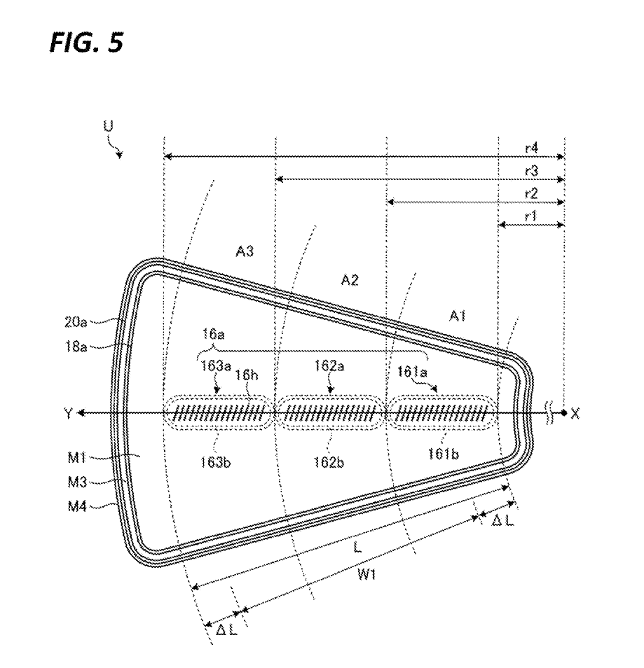

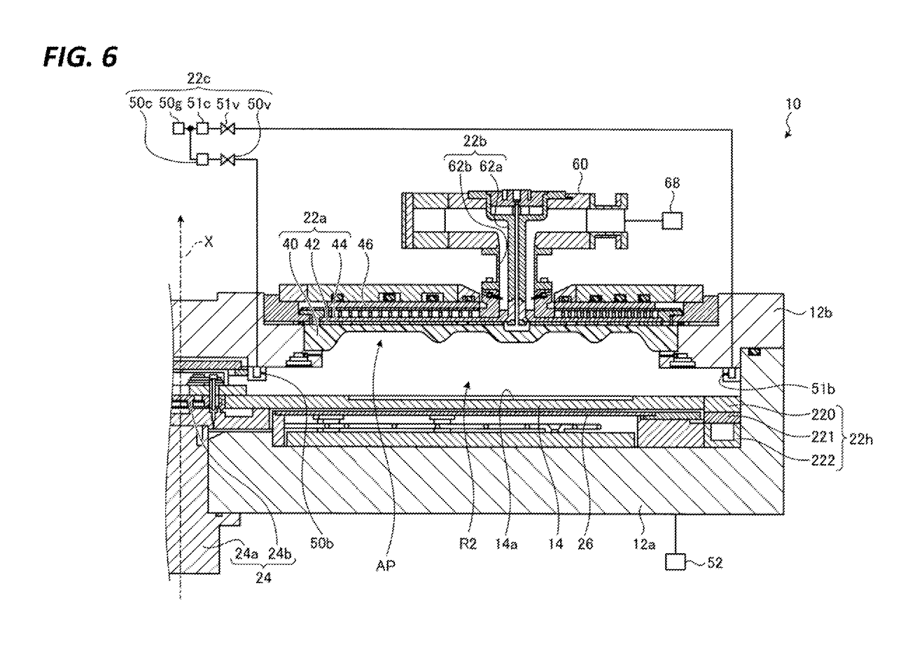

FIG. 1 is a sectional view illustrating an exemplary substrate processing apparatus 10. FIG. 2 is a schematic view illustrating the exemplary substrate processing apparatus 10 when viewed from the upper side. The sectional view along A-A in FIG. 2 is FIG. 1. FIGS. 3 and 4 are sectional views illustrating an example of a left portion of the axis X in FIG. 1 in an enlarged scale. FIG. 5 is a view illustrating an example of a bottom surface of a unit U. FIG. 6 is a sectional view illustrating an example of a right portion of the axis X in FIG. 1 in an enlarged scale. The substrate processing apparatus 10 illustrated in FIGS. 1 to 6 mainly includes a processing container 12, a mounting table 14, a first gas supply section 16, an exhaust section 18, a second gas supply section 20, and a plasma generating unit 22.

As illustrated in FIG. 1, the processing container 12 includes a lower member 12a and an upper member 12b. The lower member 12a has a substantially cylindrical shape of which the top side is opened, and forms a concave portion including a side wall and a bottom wall which form a processing chamber C. The upper member 12b is a cover having a substantially cylindrical shape, and forms the processing chamber C by closing the upper opening of the concave portion of the lower member 12a. An elastic sealing member for sealing the processing chamber C, e.g., an O-ring, is provided in the outer periphery portion between the lower member 12a and the upper member 12b.

The substrate processing apparatus 10 includes the mounting table 14 within the processing chamber C formed by the processing container 12. The mounting table 14 is rotationally driven around the axis X by a driving mechanism 24. The driving mechanism 24 includes a driving device 24a such as, for example, a motor, and a rotation shaft 24b, and is attached to the lower member 12a of the processing container 12.

The rotation shaft 24b extends to the inside of the processing chamber C with the axis X as a central axis. The rotation shaft 24b rotates about the axis X by a driving force transferred from the driving device 24a. The central portion of the mounting table 14 is supported by the rotation shaft 24b. Accordingly, the mounting table 14 rotates around the axis X according to the rotation of the rotation shaft 24b. An elastic sealing member such as, for example, an O-ring is provided between the lower member 12a of the processing container 12 and the driving mechanism 24 to seal the processing chamber C.

The substrate processing apparatus 10 includes a heater 26 under the mounting table 14 within the processing chamber C in order to heat a substrate W placed on the mounting table 14. Specifically, the heater 26 heats the substrate W by heating the mounting table 14.

For example, as illustrated in FIG. 2, the processing container 12 is a substantially cylindrical container with the axis X as a central axis, and includes the processing chamber C therein. The unit U including an injection section 16a is provided in the processing chamber C. The processing container 12 is formed of a metal such as, for example, Al (aluminum) of which the inner surface has been subjected to an anti-plasma treatment such as, for example, an alumite treatment or spraying of Y₂O₃ (yttrium oxide). The substrate processing apparatus 10 includes a plurality of plasma generating units 22 within the processing container 12.

Each of the plasma generating units 22 includes an antenna 22a on the upper side of the processing container 12 to output microwaves. In the present exemplary embodiment, the outer shape of each antenna 22a is formed in a triangular shape with rounded corners. In the outer shape of each antenna 22a, three straight sides are present when viewed in the direction of the axis X, and the three sides are included in the sides of a triangle surrounding the outer shape of the antenna 22a. In the present exemplary embodiment, the triangle surrounding the outer shape of the antenna 22a is, for example, an equilateral triangle, when viewed in the direction of the axis X, and an angle formed between adjacent sides is, for example, 60°. In FIG. 2, three antennas 22a are provided on the upper side of the processing container 12, but the number of the antennas 22a is not limited thereto. The number may be two or less, or four or more.

For example, as illustrated in FIG. 2, the substrate processing apparatus 10 includes the mounting table 14 that has a plurality of substrate placing regions 14a on the top surface thereof. The mounting table 14 is a substantially disk-shaped member with the axis X as a central axis. On the top surface of the mounting table 14, the plurality of substrate placing regions 14a (five substrate placing regions in the example of FIG. 2) each configured to place a substrate W thereon are formed concentrically around the axis X. Substrates W are disposed within the substrate placing regions 14a, respectively, and the substrate placing regions 14a support the substrates W so that when the mounting table 14 is rotated, the substrates W are not deviated therefrom. Each substrate placing region 14a is a substantially circular recessed portion having a shape that is substantially the same as that of a substantially circular substrate W. The diameter of the recessed portion of each substrate placing region 14a is substantially the same as the diameter W1 of the substrate W placed therein. That is, the diameter of the recessed portion of each substrate placing region 14a only has to be set such that the placed substrate W is fitted in the recessed portion to be fixed without being moved from the fitted position by a centrifugal force even if the mounting table 14 is rotated.

The substrate processing apparatus 10 includes a gate valve G on the outer periphery of the processing container 12. The gate valve G is configured to allow the substrate W to be carried into and out of the processing chamber C therethrough using a conveyance device such as, for example, a robot arm. The substrate processing apparatus 10 includes an exhaust section 22h under the outer periphery of the mounting table 14 along the periphery of the mounting table 14. An exhaust device 52 is connected to the exhaust section 22h. The exhaust section 22h includes a plurality of exhaust ports in a region of an angle θ2 adjacent to a region of an angle θ1 in which an antenna 22a is provided in the rotation direction of the mounting table 14 when viewed in the axis X direction. The substrate processing apparatus 10 maintains the pressure within the processing chamber C at a target pressure by controlling the operation of the exhaust device 52, and exhausting the gas within the processing chamber C from the exhaust ports.

For example, as illustrated in FIG. 2, the processing chamber C includes a first region R1 and a second region R2 arranged on the circumference around the axis X. The substrate W placed on a substrate placing region 14a sequentially passes through the first region R1 and the second region R2 while the mounting table 14 is rotated. In the present exemplary embodiment, the mounting table 14 illustrated in FIG. 2 is rotated, for example, clockwise when viewed from the top side. The second region R2 is an example of a plasma processing region.

For example, as illustrated in FIGS. 3 and 4, the first gas supply section 16 includes an inside gas supply section 161, an intermediate gas supply section 162, and an outside gas supply section 163. Above the first region R1, the unit U configured to perform the supply, purging, and exhaust of a gas is provided to face the top surface of the mounting table 14, for example, as illustrated in FIGS. 3 and 4. The unit U has a structure in which a first member M1, a second member M2, a third member M3, and a fourth member M4 are stacked in this order. The unit U is attached to the processing container 12 to be abutted on the bottom surface of the upper member 12b of the processing container 12.

For example, as illustrated in FIGS. 3 and 4, in the unit U, a gas supply path 161p, a gas supply path 162p, and a gas supply path 163p are formed to penetrate the second to fourth members M2 to M4. The upper end of the gas supply path 161p is connected to a gas supply path 121p provided in the upper member 12b of the processing container 12. A gas supply source 16g of a precursor gas is connected to the gas supply path 121p through a valve 161v and a flow rate controller 161c such as, for example, a mass flow controller. The lower end of the gas supply path 161p is connected to a buffer space 161d which is formed between the first member M1 and the second member M2, and surrounded by an elastic member 161b such as, for example, an O-ring. The buffer space 161d is connected to injection ports 16h of an inside injection section 161a provided in the first member M1.

The upper end of the gas supply path 162p is connected to a gas supply path 122p provided in the upper member 12b of the processing container 12. The gas supply source 16g of the precursor gas is connected to the gas supply path 122p through a valve 162v and a flow rate controller 162c such as, for example, a mass flow controller. The lower end of the gas supply path 162p is connected to a buffer space 162d which is formed between the first member M1 and the second member M2, and surrounded by an elastic member 162b such as, for example, an O-ring. The buffer space 162d is connected to injection ports 16h of an intermediate injection section 162a provided in the first member M1.

The upper end of the gas supply path 163p is connected to a gas supply path 123p provided in the upper member 12b of the processing container 12. The gas supply source 16g of the precursor gas is connected to the gas supply path 123p through a valve 163v and a flow rate controller 163c such as, for example, a mass flow controller. The lower end of the gas supply path 163p is connected to a buffer space 163d which is formed between the first member M1 and the second member M2, and surrounded by an elastic member 163b such as, for example, an O-ring. The buffer space 163d is connected to injection ports 16h of an outside injection section 163a provided in the first member M1.

The buffer space 161d of the inside gas supply section 161, the buffer space 162d of the intermediate gas supply section 162, and the buffer space 163d of the outside gas supply section 163 form independent spaces, respectively, for example, as illustrated in FIGS. 3 and 4. Then, the flow rate of the precursor gas that passes through each buffer space is independently controlled by corresponding one of the flow rate controller 161c, the flow rate controller 162c, and the flow rate controller 163c.

In the unit U, a gas supply path 20r is formed to penetrate the fourth member M4, for example, as illustrated in FIGS. 3 and 4. The upper end of the gas supply path 20r is connected to a gas supply path 12r provided in the upper member 12b of the processing container 12. A gas supply source 20g of a purge gas is connected to the gas supply path 12r through a valve 20v and a flow rate controller 20c.

The lower end of the gas supply path 20r is connected to a space 20d formed between the bottom surface of the fourth member M4 and the top surface of the third member M3. In the fourth member M4, a recessed portion is formed to accommodate the first to third members M1 to M3. A gap 20p is formed between the inside surface of the fourth member M4 that forms the recessed portion, and the outside surface of the third member M3. The gap 20p is connected to the space 20d. The lower end of the gap 20p serves as an injection port 20a.

In the unit U, for example, as illustrated in FIGS. 3 and 4, an exhaust path 18q is formed to penetrate the third member M3 and the fourth member M4. The upper end of the exhaust path 18q is connected to an exhaust path 12q provided in the upper member 12b of the processing container 12. The exhaust path 12q is connected to an exhaust device 34 such as, for example, a vacuum pump. The lower end of the exhaust path 18q is connected to a space 18d formed between the bottom surface of the third member M3, and the top surface of the second member M2.

The third member M3 includes a recessed portion that accommodates the first member M1 and the second member M2. A gap 18g is formed between the outside surfaces of the first member M1 and the second member M2, and the inside surface of the third member M3 which constitutes the recessed portion provided in the third member M3. The space 18d is connected to the gap 18g. The lower end of the gap 18g serves as an exhaust port 18a.

For example, as illustrated in FIG. 5, the injection section 16a is provided along the Y axis direction that is a direction getting away from the axis X on the bottom surface of the unit U, that is, the surface facing the mounting table 14. In the region included in the processing chamber C, a region facing the injection section 16a is the first region R1. The injection section 16a injects the precursor gas to the substrate W on the mounting table 14. For example, as illustrated in FIG. 5, the injection section 16a includes the inside injection section 161a, the intermediate injection section 162a, and the outside injection section 163a.

For example, as illustrated in FIG. 5, the inside injection section 161a is formed within an inside annular region A1 which is a region included in the bottom surface of the unit U in an annular region within a range of distances r1 to r2 from the axis X. The intermediate injection section 162a is formed within an intermediate annular region A2 which is a region included in the bottom surface of the unit U in an annular region within a range of distances r2 to r3 from the axis X. The outside injection section 163a is formed within an outside annular region A3 which is a region included in the bottom surface of the unit U in an annular region within a range of distances r3 to r4 from the axis X.

The length L from r1 to r4, which is a range in which the injection section 16a formed in the bottom surface of the unit U extends in the Y axis direction, is longer than the passage length of the substrate W with the diameter W1 along the Y axis, by a predetermined distance ΔL or more in the direction toward the axis X, and is longer by a predetermined distance ΔL or more in the direction opposite to the axis X, for example, as illustrated in FIG. 5.

The inside injection section 161a, the intermediate injection section 162a, and the outside injection section 163a include the plurality of injection ports 16h, for example, as illustrated in FIG. 5. The precursor gas is injected from each of the injection ports 16h to the first region R1. Each flow rate of the precursor gas injected from the injection ports 16h of each of the inside injection section 161a, the intermediate injection section 162a, and the outside injection section 163a to the first region R1 is independently controlled by the flow rate controller 161c, the flow rate controller 162c, and the flow rate controller 163c. When the precursor gas is supplied to the first region R1, the atoms or molecules of the precursor gas are chemically adsorbed on the surface of the substrate W that has passed through the first region R1. The precursor gas is, for example, dichlorosilane (DCS), monochlorosilane, trichlorosilane, or hexachlorosilane.

At the upper side of the first region R1, for example, as illustrated in FIGS. 3 and 4, the exhaust port 18a of the exhaust section 18 is provided to face the top surface of the mounting table 14. For example, as illustrated in FIG. 5, the exhaust port 18a is formed on the bottom surface of the unit U to surround the periphery of the injection section 16a. The exhaust port 18a exhausts a gas within the processing chamber C therethrough by the operation of the exhaust device 34 such as, for example, a vacuum pump.

At the upper side of the first region R1, for example, as illustrated in FIGS. 3 and 4, the injection port 20a of the second gas supply section 20 is provided to face the top surface of the mounting table 14. For example, as illustrated in FIG. 5, the injection port 20a is formed on the bottom surface of the unit U to surround the periphery of the exhaust port 18a. The second gas supply section 20 injects a purge gas to the first region R1 through the injection port 20a. The purge gas injected by the second gas supply section 20 is an inert gas such as, for example, Ar (argon). When the purge gas is injected to the surface of the substrate W, the atoms or molecules (a residual gas component) of the precursor gas, which have been excessively chemically adsorbed to the substrate W, are removed from the substrate W. Accordingly, on the surface of the substrate W, an atomic layer or a molecular layer is formed in which the atoms or molecules of the precursor gas are chemically adsorbed.

The unit U injects the purge gas from the injection port 20a, and exhausts the purge gas from the exhaust port 18a along the surface of the mounting table 14. Accordingly, the unit U suppresses the precursor gas supplied to the first region R1 from being leaked to the outside of the first region R1. Since the unit U injects the purge gas from the injection port 20a so that the purge gas is exhausted from the exhaust port 18a along the surface of the mounting table 14, for example, a reaction gas supplied to the second region R2 or the radicals of the reaction gas may be suppressed from infiltrating into the inside of the first region R1. That is, the unit U separates the first region R1 and the second region R2 from each other through the injection of the purge gas from the second gas supply section 20 and the exhaust from the exhaust section 18.

For example, as illustrated in FIG. 6, the substrate processing apparatus 10 includes the plasma generating unit 22 in an aperture AP of the upper member 12b at the upper side of the second region R2 that is provided to face the top surface of the mounting table 14. The plasma generating unit 22 includes the antenna 22a, a coaxial waveguide 22b configured to supply microwaves to the antenna 22a, and a reaction gas supply section 22c configured to supply a reaction gas to the second region R2. In the present exemplary embodiment, for example, three apertures AP are formed in the upper member 12b, and the substrate processing apparatus 10 includes, for example, three antennas 22a.

The plasma generating unit 22 supplies microwaves from the antenna 22a and the coaxial waveguide 22b to the second region R2, and supplies a reaction gas from the reaction gas supply section 22c to the second region R2 to generate plasma of the reaction gas in the second region R2. Then, the plasma generating unit 22 performs a plasma processing on an atomic layer or a molecular layer chemically adsorbed on the substrate W. In the present exemplary embodiment, a nitrogen-containing gas is used as the reaction gas, and the plasma generating unit 22 nitrides the atomic layer or molecular layer chemically adsorbed onto the substrate W. As for the reaction gas, a nitrogen-containing gas such as, for example, N₂ (nitrogen) or NH₃ (ammonia), may be used.

For example, as illustrated in FIG. 6, in the plasma generating unit 22, the antenna 22a is airtightly disposed to close the aperture AP. The antenna 22a includes a top plate 40, a slot plate 42, and a slow wave plate 44. The top plate 40 is a substantially equilateral triangular member with rounded corners, which is formed of a dielectric material, such as, for example, an alumina ceramic. The top plate 40 is supported by the upper member 12b such that the bottom surface of the top plate 40 is exposed to the second region R2 from the aperture AP formed in the upper member 12b of the processing container 12.

The slot plate 42 is provided on the top surface of the top plate 40. The slot plate 42 is a plate-like metal member formed in a substantially equilateral triangular shape. A plurality of slot pairs are formed in the slot plate 42. Each slot pair includes two perpendicular slot holes.

The slow wave plate 44 is provided on the top surface of the slot plate 42. The slow wave plate 44 is a substantially equilateral triangular member that is formed of a dielectric material such as, for example, an alumina ceramic. A substantially cylindrical opening is formed in the slow wave plate 44 such that an outer conductor 62b of the coaxial waveguide 22b is arranged in the opening.

A metallic cooling plate 46 is provided on the top surface of the slow wave plate 44. The cooling plate 46 cools the antenna 22a through the slow wave plate 44 by a coolant that flows through a flow path formed in the cooling plate 46. The cooling plate 46 is pressed against the top surface of the slow wave plate 44 by, for example, a spring (not illustrated), and the bottom surface of the cooling plate 46 is in close contact with the top surface of the slow wave plate 44.

The coaxial waveguide 22b includes an inner conductor 62a and the outer conductor 62b. The inner conductor 62a extends through the opening of the slow wave plate 44 and the opening of the slot plate 42 from the top side of the antenna 22a. The outer conductor 62b is provided to surround the inner conductor 62a with a gap being formed between the outer peripheral surface of the inner conductor 62a and the inner peripheral surface of the outer conductor 62b. The lower end of the outer conductor 62b is connected to an opening portion of the cooling plate 46. The antenna 22a may serve as an electrode. Otherwise, an electrode provided within the processing container 12 may be used as the antenna 22a.

The substrate processing apparatus 10 includes a waveguide 60 and a microwave generator 68. The microwaves of, for example, about 2.45 GHz generated by the microwave generator 68 is propagated to the coaxial waveguide 22b through the waveguide 60, and is propagated through the gap between the inner conductor 62a and the outer conductor 62b. Then, the microwaves propagated within the slow wave plate 44 are propagated from the slot holes of the slot plate 42 to the top plate 40, and radiated from the top plate 40 to the second region R2.

The reaction gas is supplied to the second region R2 from the reaction gas supply section 22c. The reaction gas supply section 22c includes a plurality of inside injection ports 50b and a plurality of outside injection ports 51b. Each of the inside injection ports 50b is connected to a gas supply source 50g of the reaction gas through a valve 50v and a flow rate controller 50c such as, for example, a mass flow controller.

For example, as illustrated in FIGS. 2 and 6, each of the inside injection ports 50b is provided in the bottom surface of the upper member 12b of the processing container 12. For example, as illustrated in FIGS. 2 and 6, the position where each of the inside injection ports 50b is provided is closer to the axis X than the region of the antenna 22a when viewed in the axis X direction. In the present exemplary embodiment, the region of the antenna 22a refers to, for example, a region in the second region R2 where the top plate 40 of the antenna 22a is disposed when viewed in the axis X direction.

A predetermined number of inside injection ports 50b are allocated to each antenna 22a. Then, for example, as illustrated in FIG. 2, the predetermined number of inside injection ports 50b allocated to each antenna 22a are arranged along the rotation direction of the mounting table 14, in the region of the angle θ1 where the antenna 22a is provided in the rotation direction of the mounting table 14 when viewed in the axis X direction. In the present exemplary embodiment, for example, as illustrated in FIG. 2, three inside injection ports 50b are allocated to each antenna 22a. Then, the three inside injection ports 50b are disposed to be distributed at intervals of, for example, 20° within a range of an angle 60°, that is, the region of the angle θ1 where the antenna 22a is provided in the rotation direction of the mounting table 14.

Then, each inside injection port 50b injects the reaction gas supplied from the gas supply source 50g through the valve 50v and the flow rate controller 50c to the second region R2 under the antenna 22a in a direction getting away from the axis X. In the present exemplary embodiment, each inside injection port 50b injects the reaction gas, for example, in a surface direction of the mounting table 14. Each inside injection port 50b injects the reaction gas, for example, in a direction parallel to the surface of the substrate W placed on the substrate placing region 14a of the mounting table 14.

Each of the outside injection ports 51b is connected to the gas supply source 50g of the reaction gas through a valve 51v and a flow rate controller 51c such as, for example, a mass flow controller. For example, as illustrated in FIGS. 2 and 6, each of the outside injection ports 51b is provided in the bottom surface of the upper member 12b of the processing container 12. For example, as illustrated in FIGS. 2 and 6, the position where each of the outside injection ports 51b is provided is farther from the axis X than the region of the antenna 22a when viewed in the axis X direction.

A predetermined number of outside injection ports 51b are allocated to each antenna 22a. Then, for example, as illustrated in FIG. 2, the predetermined number of outside injection ports 51b allocated to each antenna 22a are arranged along the rotation direction of the mounting table 14, in the region of the angle θ1 where the antenna 22a is provided in the rotation direction of the mounting table 14 when viewed in the axis X direction. In the present exemplary embodiment, thirty seven outside injection ports 51b are allocated to each antenna 22a. Then, the thirty seven outside injection ports 51b are disposed to be distributed at intervals of, for example, about 1.6° within a range of an angle 60°, that is, the region of the angle θ1 where the antenna 22a is provided in the rotation direction of the mounting table 14.

Then, each outside injection port 51b injects the reaction gas supplied from the gas supply source 50g through the valve 51v and the flow rate controller 51c to the second region R2 under the antenna 22a in a direction approaching the axis X. In the present exemplary embodiment, each outside injection port 51b injects the reaction gas, for example, in a surface direction of the mounting table 14. Each outside injection port 51b injects the reaction gas, for example, in a direction parallel to the surface of the substrate W placed on the substrate placing region 14a of the mounting table 14. For example, as illustrated in FIG. 6, the inside injection ports 50b and the outside injection ports 51b are attached to the bottom surface of the upper member 12b as members separate from the upper member 12b that covers the upper side of the processing container 12, or the antenna 22a. Accordingly, the inside injection ports 50b and the outside injection ports 51b may be easily detached from the upper member 12b or the antenna 22a so that the maintenance of the inside injection ports 50b and the outside injection ports 51b can be facilitated.

In the present exemplary embodiment, the flow rates of the reaction gas injected from the inside injection ports 50b and the outside injection ports 51b are independently controlled by the flow rate controller 50c and the flow rate controller 51c, respectively. The flow rate controller 50c and the flow rate controller 51c may be provided in each antenna 22a so that the flow rates of the reaction gas injected from the inside injection ports 50b and the outside injection ports 51b may be independently controlled for each antenna 22a.

The plasma generating unit 22 supplies the reaction gas to the second region R2 by the plurality of inside injection ports 50b and the plurality of outside injection ports 51b, and radiates microwaves to the second region R2 by the antenna 22a. Accordingly, the plasma generating unit 22 generates plasma of the reaction gas in the second region R2.

For example, as illustrated in FIG. 2, on the periphery of the mounting table 14, an exhaust section 22h is provided. For example, as illustrated in FIG. 6, the exhaust section 22h includes a groove portion 222 of which the upper portion is opened, and a lid portion 221 provided on the upper side of the groove portion 222. The groove portion 222 is connected to the exhaust device 52. The lid portion 221 includes a plurality of exhaust ports in an exhaust region 220h, that is, a region of angle θ2 adjacent to a region of angle θ1 in which an antenna 22a is provided in the rotation direction of the mounting table 14 when viewed in the axis X direction, for example, in the substrate processing apparatus 10 illustrated in FIG. 2. In the region of the angle θ1 in which the antenna 22a is provided, the exhaust ports are not formed in the lid portion 221.

A spacer 220 is formed below the outside injection ports 51b, on the lid portion 221. The spacer 220 is formed on the periphery of the mounting table 14, in the region of the angle θ1 in which the antenna 22a is provided in the rotation direction of the mounting table 14 when viewed in the axis X direction. For example, as illustrated in FIG. 6, the spacer 220 has a thickness which is substantially the same as the height from the top surface of the lid portion 221 to the top surface of the mounting table 14. The spacer 220 suppresses an increase of a flow velocity of a gas caused by the level difference between the mounting table 14 and the lid portion 221 at the underside of the outside injection ports 51b.

The exhaust section 22h exhausts a gas within the processing chamber C through the groove portion 222 from the plurality of exhaust ports formed in the lid portion 221, by the operation of the exhaust device 52 in each exhaust region 220h. The position, size and number of the exhaust ports formed in the lid portion 221, that is, the exhaust ports formed in each exhaust region 220h, are adjusted so that the exhaust amounts from the respective exhaust regions 220h may be substantially equal to each other.

For example, as illustrated in FIG. 1, the substrate processing apparatus includes a controller 70 configured to control respective elements of the substrate processing apparatus 10. The controller 70 may be a computer including, for example, a control device such as, for example, a central processing unit (CPU), a storage device such as, for example, a memory, and an input/output device. When the CPU is operated according to a control program stored in the memory, the controller 70 controls the respective elements of the substrate processing apparatus 10.

The controller 70 transmits a control signal for controlling the rotation speed of the mounting table 14 to the driving device 24a. The controller 70 transmits a control signal for controlling the temperature of the substrate W to a power supply unit connected to the heater 26. The controller 70 transmits a control signal for controlling the flow rate of the precursor gas to the valves 161v to 163v and the flow rate controllers 161c to 163c. The controller 70 transmits a control signal for controlling the exhaust volume of the exhaust device 34 connected to the exhaust port 18a, to the exhaust device 34.

The controller 70 transmits a control signal for controlling the flow rate of the purge gas to the valve 20v and the flow rate controller 20c. The controller 70 transmits a control signal for controlling the transmission power of microwaves to the microwave generator 68. The controller 70 transmits a control signal for controlling the flow rate of the reaction gas to the valve 50v, the valve 51V, the flow rate controller 50c, and the flow rate controller 51c. The controller 70 transmits a control signal for controlling the exhaust volume from the exhaust section 22h to the exhaust device 52.

By the substrate processing apparatus 10 configured as described above, the precursor gas is injected from the first gas supply section 16 onto the substrate W, and the excessively chemically adsorbed precursor gas is removed from the substrate W by the second gas supply section 20. Then, the substrate W is exposed to the plasma of the reaction gas generated by the plasma generating unit 22. The substrate processing apparatus 10 repeats the operations described above on the substrate W so as to form a film with a predetermined thickness on the substrate W.

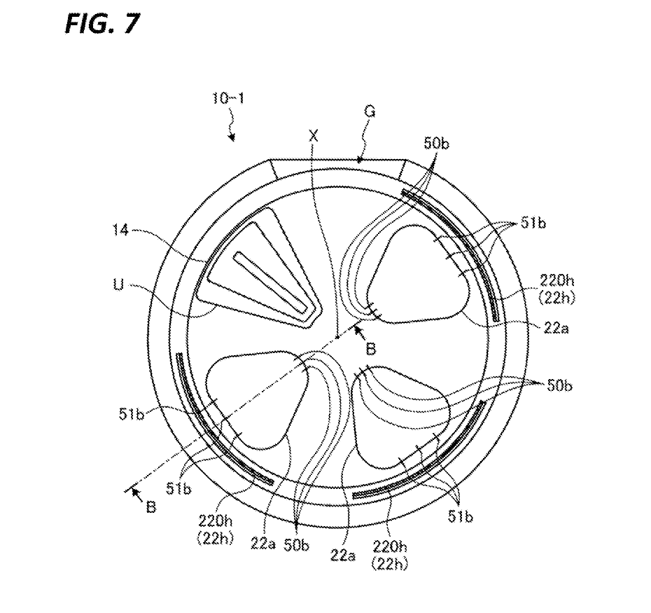

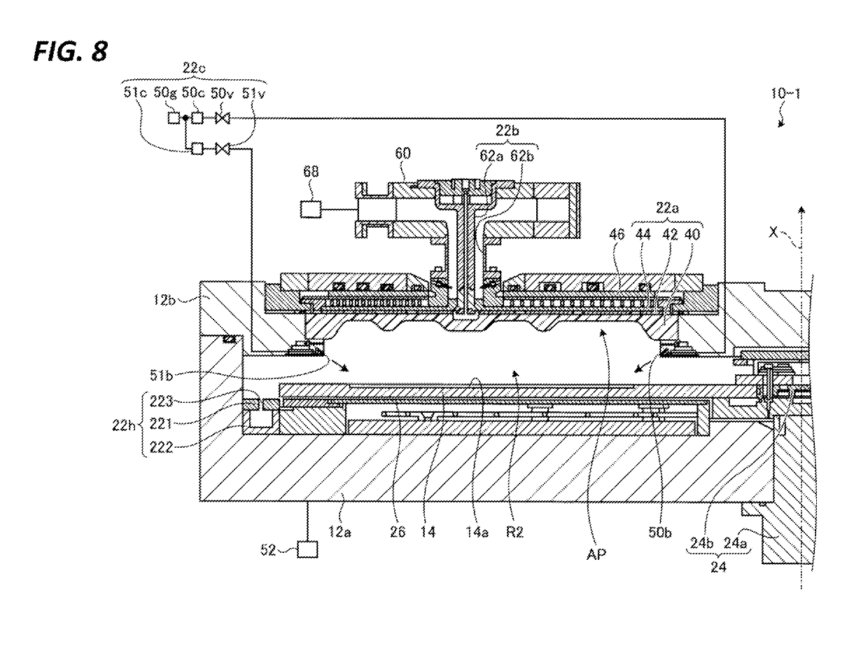

Hereinafter, Examples of the substrate processing apparatus 10, that is, the substrate processing apparatuses 10-1 to 10-3, will be described. FIG. 7 is a schematic view illustrating an exemplary substrate processing apparatus 10-1 of Example 1 when viewed from the upper side. FIG. 8 is a sectional view illustrating the exemplary substrate processing apparatus 10-1 in Example 1. FIG. 8 illustrates a section taken along B-B in the substrate processing apparatus 10-1 illustrated in FIG. 7.

For example, as illustrated in FIG. 7, the substrate processing apparatus 10-1 in Example 1 includes three inside injection ports 50b for each antenna 22a, at the side close to the axis X within the region of the antenna 22a. For example, as illustrated in FIG. 8, each of the inside injection ports 50b is provided at a position farther from the axis X than the axis X-side outer periphery of the top plate 40 of the antenna 22a. For example, as indicated by arrow illustrated in FIG. 8, each inside injection port 50b obliquely downwardly injects a reaction gas toward a position on the mounting table 14 where the axis X-side edge of the substrate W placed on the substrate placing region 14a passes.

For example, as illustrated in FIG. 7, the substrate processing apparatus 10-1 in Example 1 includes three outside injection ports 51b for each antenna 22a, at the side far from the axis X within the region of the antenna 22a. For example, as illustrated in FIG. 8, each of the outside injection ports 51b is provided at a position closer to the axis X than the outer periphery of the top plate 40 of the antenna 22a at the side far from the axis X. For example, as indicated by arrow illustrated in FIG. 8, each outside injection port 51b obliquely downwardly injects a reaction gas toward a position on the mounting table 14 where the edge of the substrate W placed on the substrate placing region 14a, at the side far from the axis X, passes. In the substrate processing apparatus 10-1 in Example 1, the inside injection ports 50b and the outside injection ports 51b are provided within the upper member 12b, for example, as illustrated in FIG. 8.

For example, as illustrated in FIG. 7, in the substrate processing apparatus 10-1 in Example 1, the exhaust regions 220h of the exhaust section 22h are provided along the periphery of the mounting table 14. For example, as illustrated in FIG. 8, in the region of the angle where each antenna 22a is provided, the lid portion 221 in which a plurality of exhaust ports 223 are formed is provided on the groove portion 222. The exhaust section 22h exhausts a gas within the processing chamber C through the groove portion 222 from the plurality of exhaust ports 223 formed in the lid portion 221 by the operation of the exhaust device 52 in each of the exhaust regions 220h.

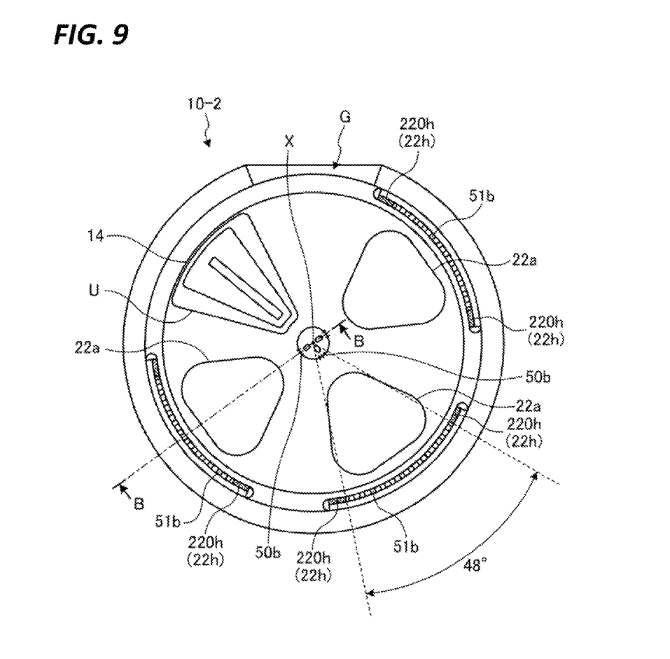

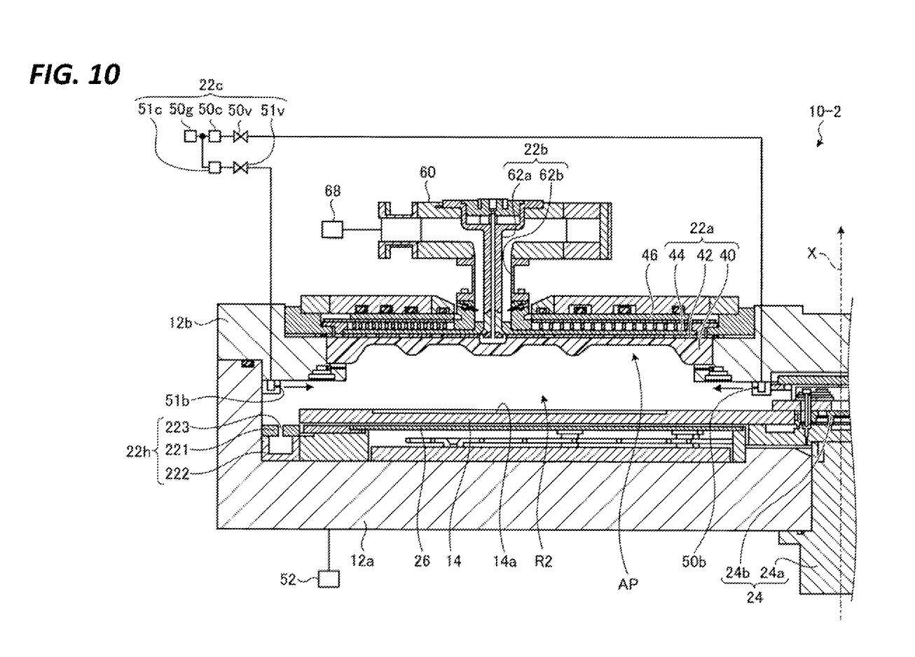

FIG. 9 is a schematic view illustrating an exemplary substrate processing apparatus 10-2 of Example 2 when viewed from the upper side. FIG. 10 is a sectional view illustrating the exemplary substrate processing apparatus 10-2 in Example 2. FIG. 10 illustrates a section taken along B-B in the substrate processing apparatus 10-2 illustrated in FIG. 9.

For example, as illustrated in FIG. 9, the substrate processing apparatus 10-2 in Example 2 includes three inside injection ports 50b for each antenna 22a, at a position closer to the axis X than the region of the antenna 22a. For example, as indicated by arrow illustrated in FIG. 10, each inside injection port 50b injects a reaction gas in a direction getting away from the axis X along the surface direction of the mounting table 14. Each inside injection port 50b injects the reaction gas, for example, in a direction parallel to the surface of the substrate W placed on the substrate placing region 14a of the mounting table 14.

For example, as illustrated in FIG. 9, the substrate processing apparatus 10-2 in Example 2 includes seventy five (75) outside injection ports 51b for each antenna 22a, at the side farther from the axis X than the region of the antenna 22a. The range of an angle in which the outside injection ports 51b are provided for each antenna 22a is 48°. For example, as indicated by arrow illustrated in FIG. 10, each outside injection port 51b injects a reaction gas in a direction approaching the axis X along the surface direction of the mounting table 14. Each outside injection port 51b injects the reaction gas, for example, in a direction parallel to the surface of the substrate W placed on the substrate placing region 14a of the mounting table 14. For example, as illustrated in FIG. 10, in the substrate processing apparatus 10-2 in Example 2, the inside injection ports 50b and the outside injection ports 51b are attached to the bottom side of the upper member 12b as members separate from the upper member 12b or the antenna 22a. Accordingly, the inside injection ports 50b and the outside injection ports 51b may be easily detached from the upper member 12b or the antenna 22a so as to facilitate the maintenance of the inside injection ports 50b and the outside injection ports 51b.

For example, as illustrated in FIG. 9, in the substrate processing apparatus 10-2 in Example 2, the exhaust regions 220h of the exhaust section 22h are provided along the periphery of the mounting table 14. For example, as illustrated in FIG. 10, in the region of the angle where each antenna 22a is provided, the lid portion 221 in which a plurality of exhaust ports 223 are formed is provided on the groove portion 222. In the substrate processing apparatus 10-2 in Example 2, the exhaust regions 220h are provided below the outside injection ports 51b. The exhaust section 22h exhausts a gas within the processing chamber C through the groove portion 222 from the plurality of exhaust ports 223 formed in the lid portion 221 by the operation of the exhaust device 52 in each of the exhaust regions 220h.

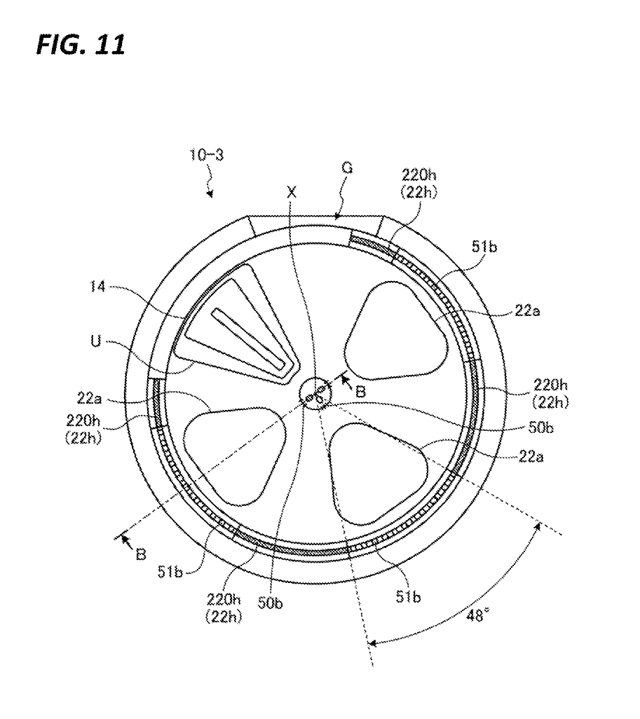

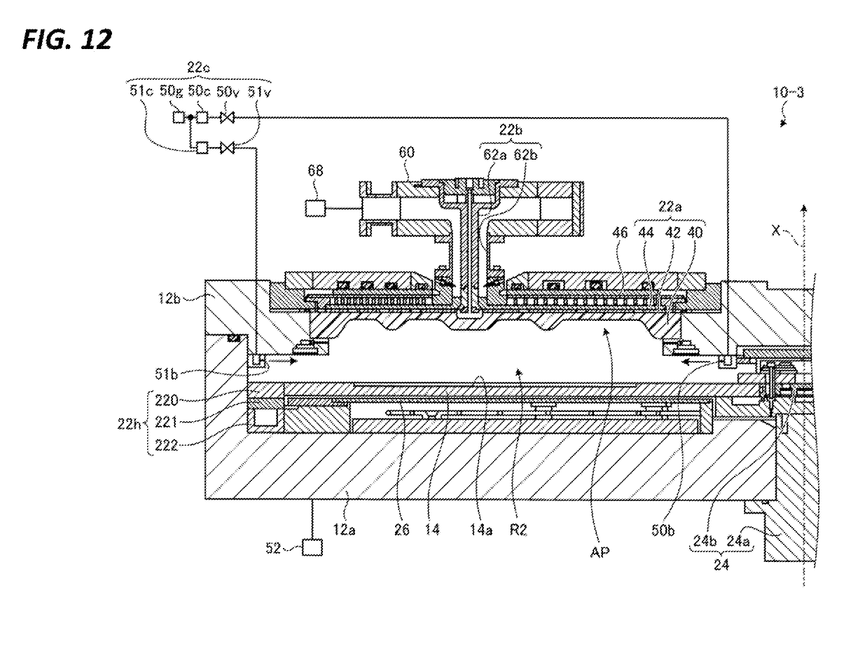

FIG. 11 is a schematic view illustrating an exemplary substrate processing apparatus 10-3 of Example 3 when viewed from the upper side. FIG. 12 is a sectional view illustrating the exemplary substrate processing apparatus 10-3 in Example 3. FIG. 12 illustrates a section taken along B-B in the substrate processing apparatus 10-3 illustrated in FIG. 11.

For example, as illustrated in FIG. 11, the substrate processing apparatus 10-3 in Example 3 includes three inside injection ports 50b for each antenna 22a, at a position closer to the axis X than the region of the antenna 22a. For example, as indicated by arrow illustrated in FIG. 12, each inside injection port 50b injects a reaction gas in a direction getting away from the axis X along the surface direction of the mounting table 14. Each inside injection port 50b injects the reaction gas, for example, in a direction parallel to the surface of the substrate W placed on the substrate placing region 14a of the mounting table 14.

For example, as illustrated in FIG. 11, the substrate processing apparatus 10-3 in Example 3 includes seventy five (75) outside injection ports 51b for each antenna 22a, at the side farther from the axis X than the region of the antenna 22a. The range of an angle in which the outside injection ports 51b are provided for each antenna 22a is 48°. For example, as indicated by arrow illustrated in FIG. 12, each outside injection port 51b injects a reaction gas in a direction approaching the axis X along the surface direction of the mounting table 14. Each outside injection port 51b injects the reaction gas, for example, in a direction parallel to the surface of the substrate W placed on the substrate placing region 14a of the mounting table 14. In the substrate processing apparatus 10-3 in Example 3 as well, the inside injection ports 50b and the outside injection ports 51b are attached to the bottom side of the upper member 12b as members separate from the upper member 12b, for example, as illustrated in FIG. 12.

For example, as illustrated in FIG. 11, in the substrate processing apparatus 10-3 in Example 3, the exhaust regions 220h of the exhaust section 22h are provided along the periphery of the mounting table 14. The exhaust regions 220h are provided at the periphery of the mounting table 14 in regions of the angle where the antennas 22a are not provided. In the substrate processing apparatus 10-3 in Example 3, a spacer 220 is formed below the outside injection ports 51b, on the lid portion 221. The spacer 220 is formed at the periphery of the mounting table 14, in the angle range of 48° in which the outside injection ports 51b are provided. The spacer 220 has a thickness which is substantially the same as the height from the top surface of the lid portion 221 to the top surface of the mounting table 14. The spacer 220 suppresses an increase of a flow velocity of a gas caused by the level difference between the mounting table 14 and the lid portion 221 at the underside of the outside injection ports 51b.

FIGS. 13 to 18 are views illustrating examples of a film thickness distribution on the substrate W in Examples 1 to 3 when a flow rate of a reaction gas and a radical distribution control (RDC) were changed. The RDC is indicated by a ratio of the flow rate of a reaction gas injected from the inside injection ports 50b with respect to a total flow rate of the flow rate of the reaction gas injected from the inside injection ports 50b and the flow rate of a reaction gas injected from the outside injection ports 51b, for each antenna 22a. In FIGS. 13 to 18, the Y axis indicates a direction getting away from the axis X, on the surface of the substrate W, and “0” on the Y axis indicates the center of the substrate W.

FIG. 13 illustrates a film thickness distribution of the substrate W when the total flow rate of the reaction gas is 630 sccm, and the RDC is 0%. FIG. 14 illustrates a film thickness distribution of the substrate W when the total flow rate of the reaction gas is 630 sccm, and the RDC is 100%. The reaction gas used in the experiments of FIGS. 13 and 14 is a mixed gas of NH₃/H₂/Ar, at respective flow rates of 86/464/80 sccm.

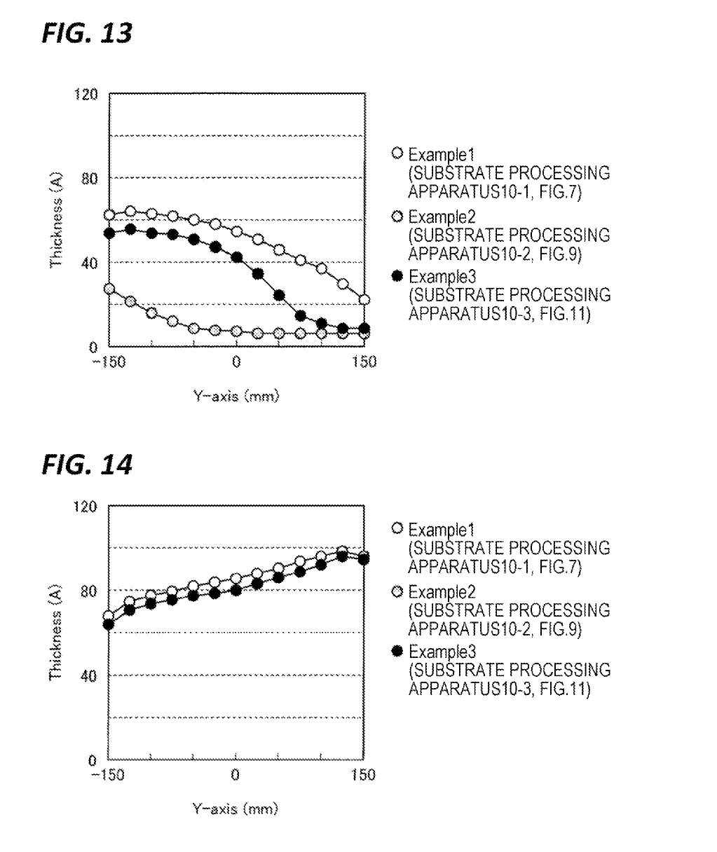

FIG. 15 illustrates a film thickness distribution of the substrate W when the total flow rate of the reaction gas is 1730 sccm, and the RDC is 0%. FIG. 16 illustrates a film thickness distribution of the substrate W when the total flow rate of the reaction gas is 1730 sccm, and the RDC is 100%. The flow rate ratio of a reaction gas used in the experiments of FIGS. 15 and 16 is NH₃/H₂/Ar=260/1390/80 sccm.

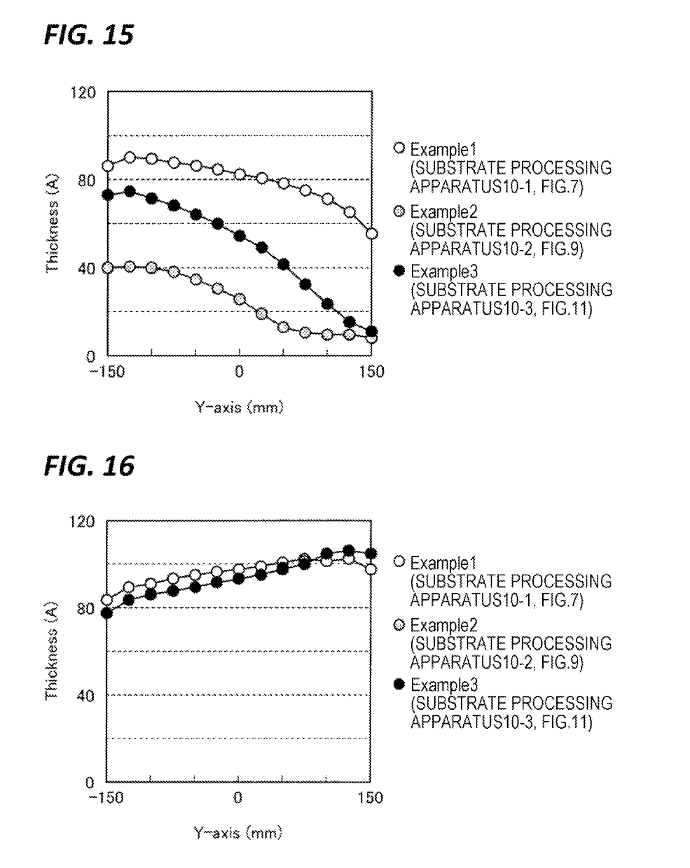

FIG. 17 illustrates a film thickness distribution of the substrate W when the total flow rate of the reaction gas is 4830 sccm, and the RDC is 0%. FIG. 18 illustrates a film thickness distribution of the substrate W when the total flow rate of the reaction gas is 4830 sccm, and the RDC is 100%. The flow rate ratio of a reaction gas used in the experiments of FIGS. 17 and 18 is NH₃/H₂/Ar=750/4000/80 sccm.

Referring to FIGS. 13, 15, and 17, when the RDC is 0%, that is, when the reaction gas is injected from only the outside injection ports 51b, in Examples 2 and 3, the growth rate (G/R) is lower than that in Example 1. In Example 1, since the number of the outside injection ports 51b is smaller than those of Example 2 and Example 3, the flow velocity of the reaction gas in Example 1 is higher even when the reaction gas is injected at the same flow rate. Thus, it is thought that, in Example 1, most of the reaction gas injected from the outside injection ports 51b flowed in a direction getting away from the exhaust section 22h provided at the periphery of the mounting table 14, and thus the amount of the reaction gas flowing on the substrate W became larger than those of Example 2 and Example 3. However, when the flow velocity of the reaction gas flowing on the substrate W is excessively high, the elements of the reaction gas on the substrate W are not sufficiently dissociated, and the quality of the film formed on the substrate W is deteriorated. The quality of the film formed on the substrate W may be evaluated using, for example, a wet etching rate ratio (WERR).

Meanwhile, in Examples 2 and 3, since the number of the outside injection ports 51b is larger than that of Example 1, the flow velocity of the reaction gas is lower than that in Example 1 when the reaction gas is injected at a flow rate that is the same as that of Example 1. Thus, in Examples 2 and 3, the improvement of the quality of the film formed on the substrate W may be expected. However, in Examples 2 and 3, the flow velocity of the reaction gas is low, and the exhaust regions 220h are provided in the vicinity of the outside injection ports 51b. Thus, most of the reaction gas injected from the outside injection ports 51b flows into the exhaust regions 220h. Thus, in Examples 2 and 3, it is thought that the amount of the reaction gas flowing on the substrate W was decreased, and thus the G/R was reduced as compared to that of Example 1.

Meanwhile, in Example 2, as described in FIGS. 9 and 10, the exhaust regions 220h are provided below the outside injection ports 51b at the periphery of the mounting table 14, while in Example 3, as described in FIGS. 11 and 12, the exhaust regions 220h are not provided in the angle region where the outside injection ports 51b are arranged but provided in the angle region where the outside injection ports 51b are not arranged at the periphery of the mounting table 14. Thus, it is thought that in Example 3, the length of time the reaction gas injected from the outside injection ports 51b drifts in the space between the bottom surface of the antenna 22a and the top surface of the substrate W became longer than that in Example 2, and thus the G/R was increased as compared to that in Example 2. As described above, the G/R may be changed by changing the positional relationship between the outside injection ports 51b and the exhaust regions 220h. Also, in Example 3, it is thought that the amount of the reaction gas flowing on the substrate W may be increased by reducing the number of the outside injection ports 51b, and increasing the flow velocity of the reaction gas injected from each of the outside injection ports 51b, so that the G/R may be increased.

When FIGS. 13, 15, and 17 are compared to FIGS. 14, 16, and 18, at the RDC of 0%, the film thickness of the substrate W at the side closer to the outside injection ports 51b is larger, and at the RDC of 100%, the film thickness of the substrate W at the side closer to the inside injection ports 50b is larger. Then, referring to FIGS. 13 to 18, in Examples 2 and 3, the inclination of the film thickness distribution is larger than that in Example 1. In this manner, in Examples 2 and 3, the controllability of the film thickness distribution of the substrate W is improved as compared to that in Example 1.

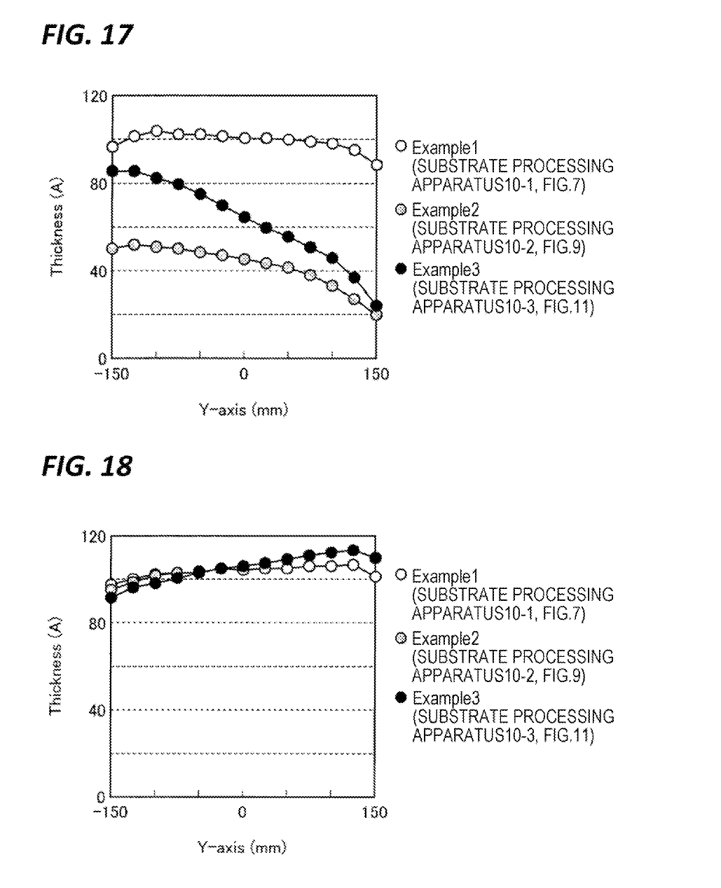

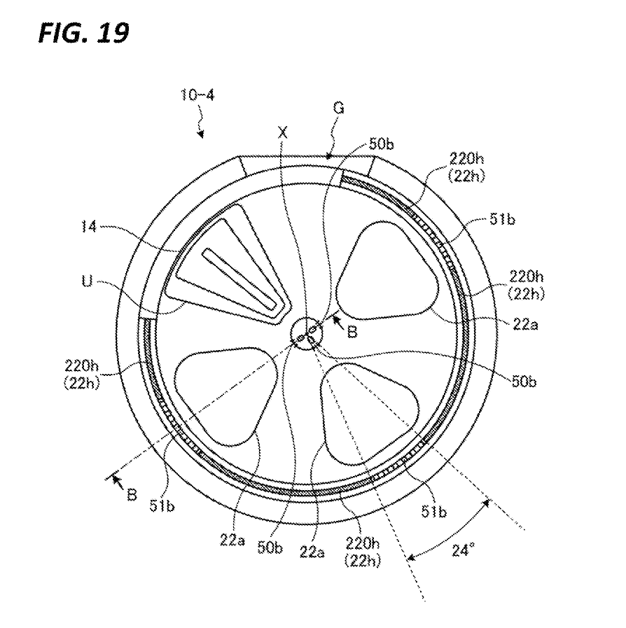

Hereinafter, descriptions will be made on an experimental result in a case where the number of the outside injection ports 51b was reduced as compared to that of Example 3. FIG. 19 is a schematic view illustrating an exemplary substrate processing apparatus 10-4 of Example 4 when viewed from the upper side. The section taken along B-B in the substrate processing apparatus 10-4 in Example 4 is the same as FIG. 12, and thus detailed descriptions thereof will be omitted.

For example, as illustrated in FIG. 19, the substrate processing apparatus 10-4 in Example 4 includes three inside injection ports 50b for each the antenna 22a, at a position closer to the axis X than the region of the antenna 22a. For example, as indicated by arrow illustrated in FIG. 12, each inside injection port 50b injects a reaction gas in a direction getting away from the axis X along the surface direction of the mounting table 14. Each inside injection port 50b injects the reaction gas, for example, in a direction parallel to the surface of the substrate W placed on the substrate placing region 14a of the mounting table 14.

For example, as illustrated in FIG. 19, the substrate processing apparatus 10-4 in Example 4 includes thirty seven outside injection ports 51b for each antenna 22a, at the side farther from the axis X than the region of the antenna 22a. In Example 4, the range of an angle in which the outside injection ports 51b are provided for each antenna 22a is 24°. For example, as indicated by arrow illustrated in FIG. 12, each outside injection port 51b injects a reaction gas in a direction approaching the axis X along the surface direction of the mounting table 14. Each outside injection port 51b injects the reaction gas, for example, in a direction parallel to the surface of the substrate W placed on the substrate placing region 14a of the mounting table 14.

For example, as illustrated in FIG. 19, in the substrate processing apparatus 10-4 in Example 4, exhaust regions 220h of the exhaust section 22h are provided along the periphery of the mounting table 14. The exhaust regions 220h are provided at the periphery of the mounting table 14 in regions of the angle where the antennas 22a are not provided. In the substrate processing apparatus 10-4 in Example 4, the spacer 220 formed below the outside injection ports 51b is formed at the periphery of the mounting table 14 in the angle range of 24° in which the outside injection ports 51b are provided.

FIGS. 20 to 25 are views illustrating examples of a film thickness distribution on the substrate when a flow rate of a reaction gas was changed in Examples 1, 4, and 5. The configuration of the substrate processing apparatus 10 in Example 5 is the same as that of the substrate processing apparatus 10 described above using FIGS. 1 to 6. FIG. 20 illustrates a film thickness distribution of the substrate W when the total flow rate of the reaction gas is 630 sccm, and the RDC is 0%. The flow rate ratio of the reaction gas used in the experiment of FIG. 20 is NH₃/H₂/Ar=86/464/80 sccm. FIG. 21 is a view illustrating a hatched portion of FIG. 20 in an enlarged scale.

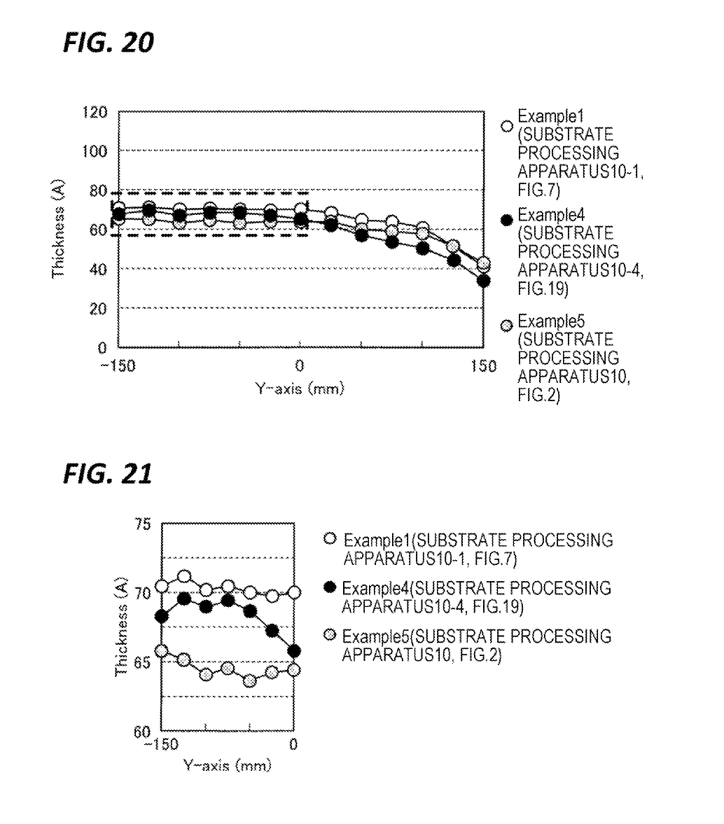

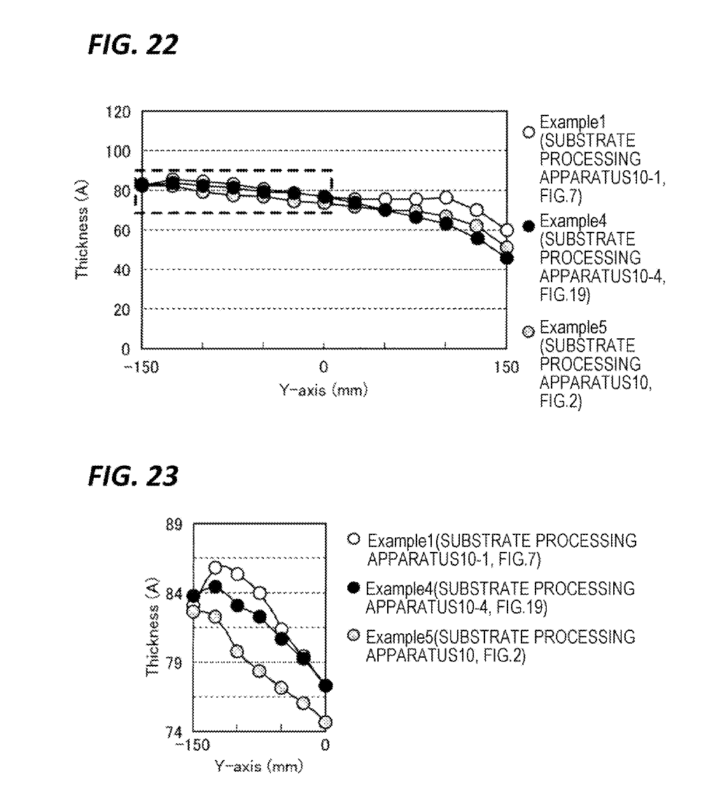

FIG. 22 illustrates a film thickness distribution of the substrate W when the total flow rate of the reaction gas is 1650 sccm, and the RDC is 0%. The flow rate ratio of the reaction gas used in the experiment of FIG. 22 is NH₃/H₂=260/1390 sccm. FIG. 23 is a view illustrating a hatched portion of FIG. 22 in an enlarged scale.

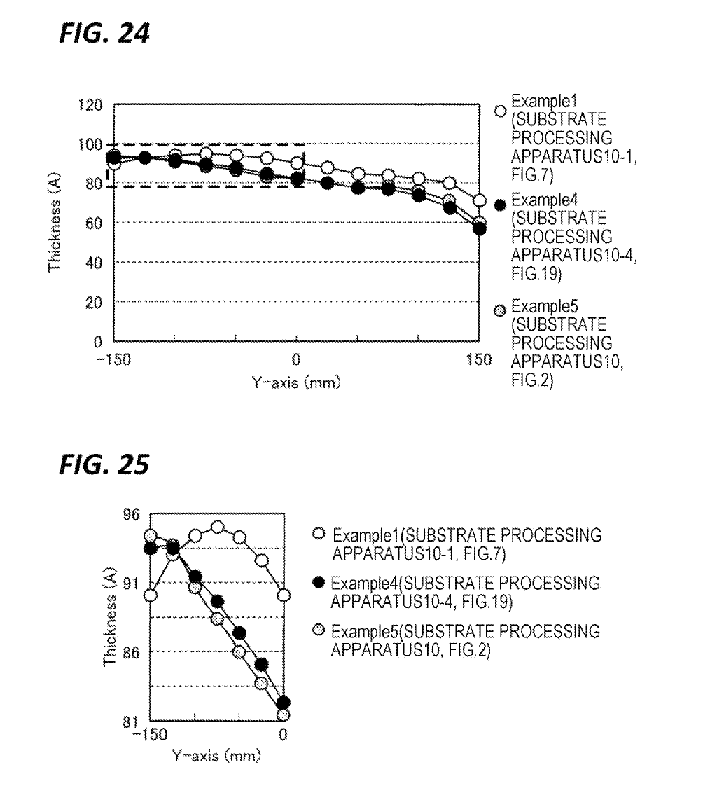

FIG. 24 illustrates a film thickness distribution of the substrate W when the total flow rate of the reaction gas is 4750 sccm, and the RDC is 0%. The flow rate ratio of the reaction gas used in the experiment of FIG. 24 is NH₃/H₂=750/4000 sccm. FIG. 25 is a view illustrating a hatched portion of FIG. 24 in an enlarged scale.

Referring to FIGS. 20 to 25, in Examples 4 and 5 in which the number of the outside injection ports 51b was reduced to 37 for each antenna 22a, the G/R was increased to the same extent as that of Example 1. In Examples 4 and 5, it is thought that since the number of the outside injection ports 51b was reduced to 37, the flow velocity of the reaction gas injected from each of the outside injection ports 51b was increased, and thus the amount of the reaction gas flowing on the substrate W was increased. Meanwhile, in Examples 4 and 5, the number of the outside injection ports 51b is 37, and in Example 1, the number of the outside injection ports 51b is 3. Accordingly, in Examples 4 and 5, the flow velocity of the reaction gas injected from each of the outside injection ports 51b is lower than the flow velocity of the reaction gas injected from each of the outside injection ports 51b in Example 1. Thus, in Examples 4 and 5, the length of time the reaction gas drifts in the space between the bottom surface of the antenna 22a and the top surface of the substrate W becomes longer than that in Example 1, and thus the probability of dissociation of elements of the reaction gas is increased. Therefore, in Examples 4 and 5, the quality of the film formed on the substrate W may be improved.

Referring to FIGS. 21, 23, and 25, in Example 1, as the flow rate of a reaction gas is increased, the G/R in the vicinity of the edge of the substrate W at the outside injection ports 51b side is relatively reduced as compared to the G/R in other regions on the substrate W. It is considered that this is caused because the flow velocity of the reaction gas injected from each of the outside injection ports 51b was increased according to an increase of the flow rate of the reaction gas, so that most of the reaction gas flowed to the axis X side, and thus the concentration of the reaction gas in the vicinity of the edge of the substrate W at the outside injection ports 51b side was relatively reduced.

In contrast, in Example 4, when the flow rate of a reaction gas is increased, in the vicinity of the edge of the substrate W at the outside injection ports 51b side, an increase of the G/R becomes slow, but a relative decrease of the G/R is not observed. In Example 5, even when the flow rate of a reaction gas is increased, in the vicinity of the edge of the substrate W at the outside injection ports 51b side, a relative decrease of the G/R is not observed, and also slowing-down of an increase of the G/R is not observed. It is considered that this is caused because the number of the outside injection ports 51b in Examples 4 and 5 is larger than that in Example 1, and thus the increment of the flow velocity with respect to the flow rate of a reaction gas is low. In Example 5, since the plurality of outside injection ports 51b are arranged to be distributed in a wider angle range than that of Example 4, the flow velocity of the reaction gas injected from the plurality of outside injection ports 51b is more quickly reduced than that in Example 4 in which the plurality of outside injection ports 51b are densely arranged. Therefore, it is thought that, in Example 5, the flow velocity of the reaction gas reaching the substrate W was more largely suppressed than that in Example 4, so that the probability of dissociation of elements of the reaction gas was kept high.

So far, an exemplary embodiment has been described. According to the substrate processing apparatus 10 of the present exemplary embodiment, the controllability of the film thickness distribution on the substrate W may be improved in the radial direction of the mounting table 14 from the rotation center of the mounting table 14.

In the exemplary embodiment described above, as for the substrate processing apparatus 10, a film forming apparatus configured to form a predetermined film on a substrate W using a PE-ALD method has been described as an example, but the disclosed technology is not limited thereto. For example, the technology disclosed in the exemplary embodiment described above may also be applied to, for example, a plasma etching apparatus (e.g., an atomic layer etching (ALE) apparatus) or an apparatus configured to perform a modifying processing using plasma as long as the apparatus performs a processing on a substrate W using plasma of a reaction gas.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a mounting table configured to place a substrate to be processed (“substrate”) thereon, and provided to be rotatable around an axis such that the substrate is moved around the axis;
an antenna provided in a plasma processing region which is one region among a plurality of regions, through which the substrate sequentially passes while moving in a circumferential direction around the axis due to rotation of the mounting table; and
a gas supply section configured to supply a reaction gas to the plasma processing region,
wherein the gas supply section includes:
an inside injection port provided at a position closer to the axis than the antenna when viewed in a direction of the axis, the inside injection port being configured to inject the reaction gas in a direction getting away from the axis, and
an outside injection port provided at a position farther from the axis than the antenna when viewed in the direction of the axis, the outside injection port being configured to inject the reaction gas in a direction approaching the axis at a flow rate which is controlled independently of a flow rate of the reaction gas injected from the inside injection port.

2. The substrate processing apparatus of claim 1, wherein the inside injection port and the outside injection port inject the reaction gas toward a region where the antenna is provided when viewed in the direction of the axis.

3. The substrate processing apparatus of claim 1, wherein the inside injection port and the outside injection port inject the reaction gas toward a direction parallel to a surface of the substrate placed on the mounting table.

4. The substrate processing apparatus of claim 1, wherein the gas supply section includes a plurality of inside injection ports and a plurality of outside injection ports.

5. The substrate processing apparatus of claim 1, wherein a plurality of antennas are provided in the plasma processing region, and
at least one inside injection port and at least one outside injection port are allocated to each of the antennas, and a flow rate of the reaction gas to be injected for each of the antennas is independently controllable.

6. The substrate processing apparatus of claim 1, further comprising:
an exhaust region provided along a periphery of the mounting table and configured to perform exhaust from a plurality of exhaust ports,
wherein the plurality of exhaust ports are formed in a region of an angle that is different from a region of an angle where the antenna is provided when viewed in the direction of the axis.

7. The substrate processing apparatus of claim 6, wherein a plurality of exhaust regions are provided along the periphery of the mounting table.

8. The substrate processing apparatus of claim 7, wherein exhaust amounts from the respective exhaust regions are equal to each other.
